(19) United States
(12) Patent Application Publication
(10) Pub. No.: US 2008/0151592 A1
(43) Pub. Date: Jun. 26, 2008

(54) Semiconductor device and method of fabricating a semiconductor device

(76) Inventors: Peter Baars, Dresden (DE); Klaus Muemmler, Dresden (DE); Stefan Tegen, Dresden (DE)

Correspondence Address: SLATER & MATSIL LLP, 17950 PRESTON ROAD, SUITE 1000, DALLAS, TX, 75252, US

(21) Appl. No.: 11/645,147

(22) Filed: Dec. 21, 2006

(51) Int. Cl. G11C 5/10; H01L 21/768

(52) U.S. Cl. 365/63; 438/618; 257/E21.575

(57) ABSTRACT

Method of fabricating a semiconductor device, comprising the steps of providing a substrate with a plurality of contact portions; forming a plurality of electrical contacts such that a contact is electrically connected to each of the contact portions, the contacts each comprising a contact area for connecting to a further part of the semiconductor device; forming an isolating region such that each contact is at least partially surrounded by the isolating region; performing an etching step in order to form a plurality of recesses in the isolating region, wherein a recess is formed adjacent to each contact; and filling the recesses with conductive material in order to enlarge the contact areas of the contacts.

### TECHNICAL FIELD

This invention generally relates to the fabrication of a semiconductor device that comprises a substrate with a plurality of contact portions and a plurality of contacts that are electrically connected to the contact portions.

### BACKGROUND

For example, a memory device such as DRAM (Dynamic Random Access Memory) or FRAM (Ferro Electric Random Access Memory) chips comprises a plurality of storage cells. Each storage cell in turn has a functional element in the form of a storage element and a selection transistor controlling charging and discharging of the storage element. Contact portions of the selection transistor are connected to the storage element via storage element contacts, wherein the contact portions and the storage element contacts are arranged in a plurality of parallel columns.

The storage elements are preferably arranged in a checkerboard layout. However, this is problematic with storage element contacts that are arranged along a line since the overlay between the contacts and the storage elements is small.

### SUMMARY OF THE INVENTION

The invention refers to a method of fabricating a semiconductor device, comprising providing a substrate with a plurality of contact portions, forming a plurality of electrical contacts such that a contact is electrically connected to each of the contact portions, the contacts each comprising a contact area for connecting to a further part of the semiconductor device. Further an isolating region is formed such that each contact is at least partially surrounded by the isolating region. An etching step is performed in order to form a plurality of recesses in the isolating region, wherein a recess is formed adjacent to each contact. The recesses are filled with conductive material in order to enlarge the contact areas of the contacts.

Furthermore, the invention refers to a substrate with a plurality of contact portions and a plurality of contacts that are electrically connected to the contact portions, wherein a contact area is arranged on top of each contact, the contact area comprising a basic portion aligned with the contact and an extension that extends from the basic portion essentially parallel to the substrate surface.

The invention allows functional elements to be arranged in a variety of layouts, such as a checkerboard layout, with an enlarged overlay to the contacts.

### BRIEF DESCRIPTION OF THE DRAWINGS

Embodiments and advantages of the invention become apparent upon reading of the detailed description of the invention, and the appended claims provided below, and upon reference to the drawings.

FIGS. 1 to 10 schematically show fabrication steps according to an embodiment of the inventive fabrication method.

### DETAILED DESCRIPTION OF ILLUSTRATIVE EMBODIMENTS

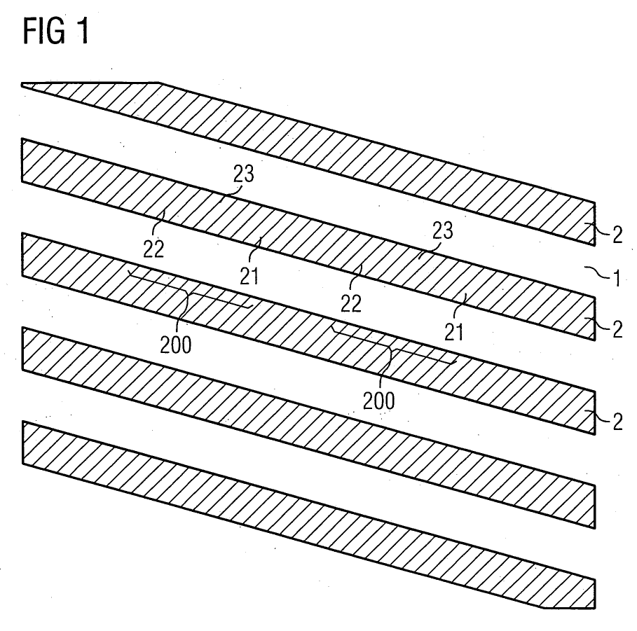

FIG. 1 depicts a semiconductor substrate 1 in which a plurality of active areas 200 for forming selection transistors of, e.g., storage cells is arranged along parallel stripes 2. For forming the active areas 200, the semiconductor substrate 1 or a layer formed on the semiconductor substrate is doped such that regions of different carrier types are produced. More particularly, the active area 200 of one selection transistor comprises contact portions in the form of first regions 22 and further contact portions in the form of second regions 21. The regions 21, 22 are of a first carrier type and are separated by a third region 23 of a second carrier type different from the first carrier type. Regions 21, 22 represent source/drain regions of the selection transistors, whereas regions 23 represent channel regions of the selection transistors.

The first region 22 (of the first carrier type) of a selection transistor representing a drain/source region of the selection transistor is to be connected to a storage element (not shown in FIG. 1) and thus is referred to as a storage element contact portion. The second region 21 of the selection transistor (also of the first carrier type) representing a source/drain region of the selection transistor is to be connected to a contact line, such as a bit line, and thus in the following is referred to as a bit line contact portion.

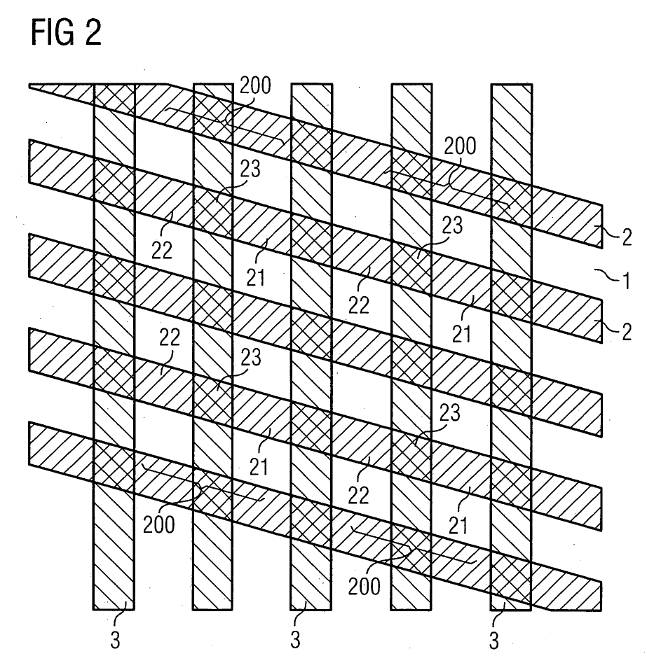

FIG. 2 shows the arrangement of a plurality of word lines 3 extending obliquely with respect to the active area stripes 2. The word lines 3 are buried within substrate 1 and electrically connect to the channel regions 23 of the selection transistors 200. The formation of buried word lines, however, is well known in the art and therefore is not explained in greater detail. Further, an isolating layer (not shown) is arranged over the substrate at least partially covering the active areas 200.

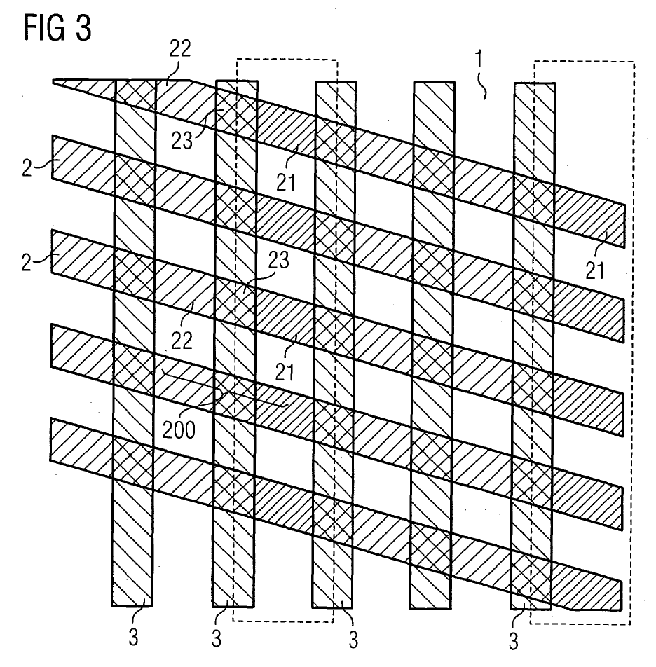

Referring to FIG. 3, employing a stripe lithography step (indicated by the dashed rectangulars), the bit line contact portions 21 are uncovered, e.g., using a dry etching step.

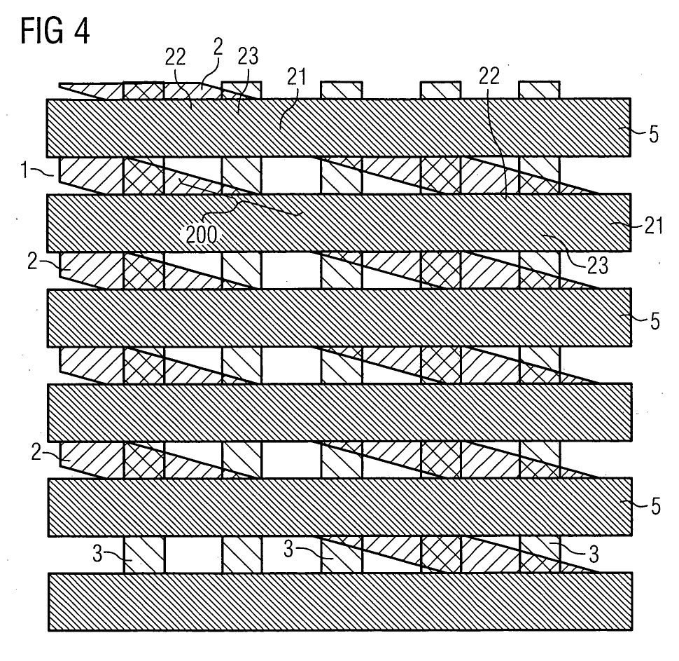

Further, as shown in FIG. 4, a plurality of parallel contact lines in the form of bit lines 5 is arranged perpendicular to the word lines 3. The bit lines 5 comprise a conductive poly silicon layer covered by a metal layer, such as a tungsten or titanium layer, which in turn is covered by an isolating layer formed of, e.g., silicon nitride. As further illustrated in FIG. 4, the bit lines 5 extend obliquely with respect to the active area stripes 2 such that they can connect to bit line contact portions 21 belonging to different active area stripes 2.

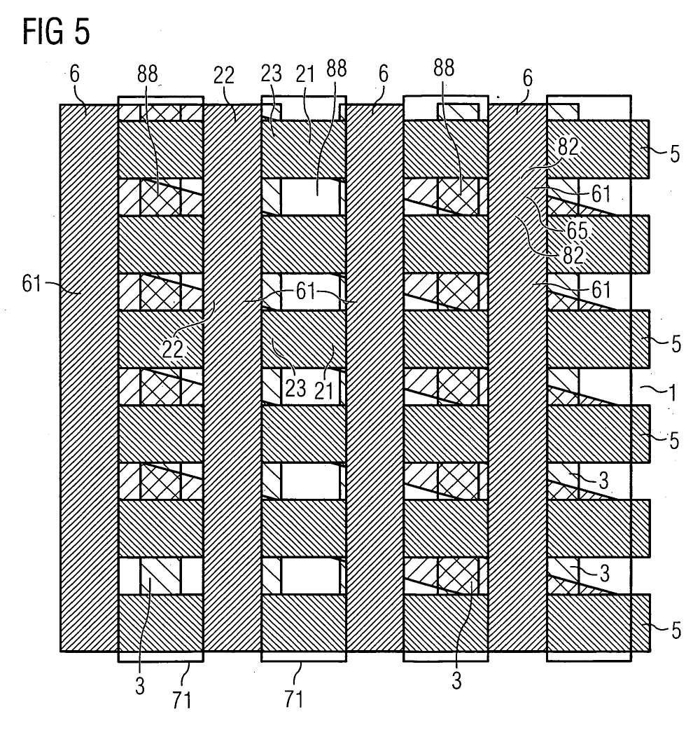

FIG. 5 depicts the generation of conductive stripes 6 (of, e.g., poly silicon) perpendicular to the bit lines 5 in order to form contacts to the storage element contact portions 22 of the selection transistors. The conductive stripes 6 are generated employing a stripe lithography step (indicated by rectangulars 71). An isolation region 88 is formed between the conductive stripes 6. The isolation region 88 comprises e.g. silicon nitride, silicon oxide and/or doped isolation materials such as BPSG—boro-phospho-silicate glass.

The conductive stripes 6 are polished (by CMP—Chemical Mechanical Polishing) with stop on the bit lines 5 such that the poly silicon of the stripes 6 is removed from the bit lines 5. Alternatively, an etching step can be employed instead of polishing. As a result, a plurality of contacts in the form of rectangular shaped storage element contacts 61 are formed between the bit lines 5, the contacts being arranged along parallel columns (contact columns). The storage element contacts 61 each are electrically connected to one of the storage element contact portions 22 of one of the selection transistors and are isolated from each other by the isolation region 88 and from the bit lines 5 by isolating spacers 82.

Due to the CMP step, the region above the active areas 200 is essentially planarized, i.e., surfaces 52, 82, 65 of the bit lines 5, of the isolating region 88 and the storage element contacts 61, respectively, facing away from the substrate extend in the same plane. After the polishing step a plurality of (essentially rectangular) storage element contacts 61 between the bit lines 5 are generated as mentioned above.

It is pointed out that the invention is of course not restricted to a particular method of generating active areas, word lines, bit lines or storage element contacts. A variety of processes are known for forming these parts; e.g., the word line has not to be a buried word line. Also, the above-mentioned process for producing the storage element contacts including the generation and polishing of conductive stripes represents an example, only. Different methods for generating storage element contacts are known (e.g., comprising a hole lithography step for the generation of the contacts).

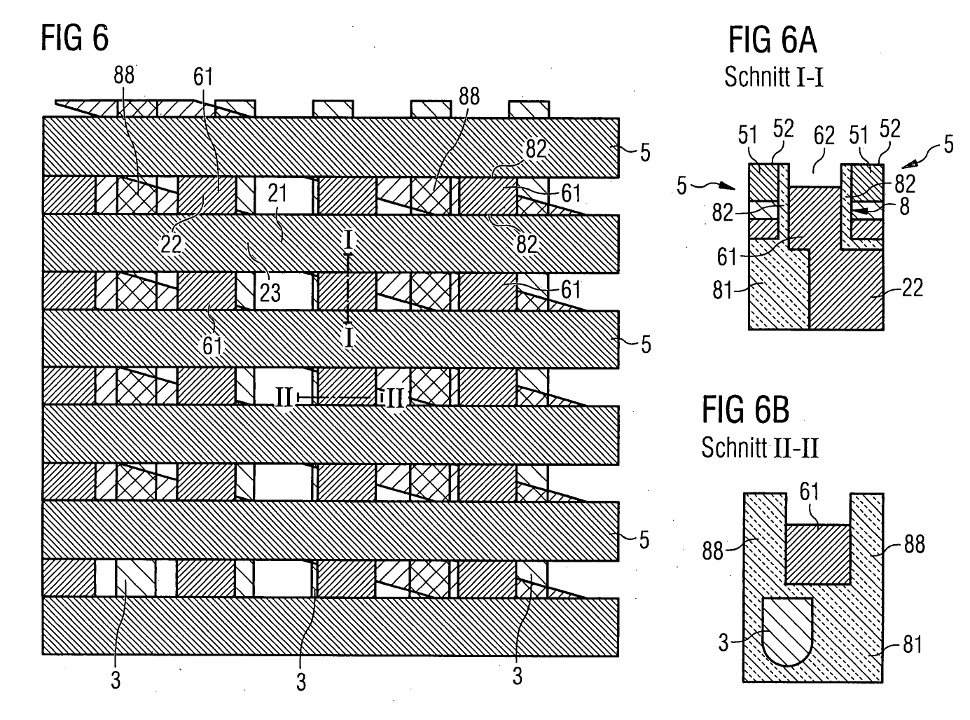

According to FIG. 6, a removal step (such as dry etching) is performed in order to reduce the height (measured perpendicular to the substrate surface) of the storage element contacts 61, wherein an upper portion of the contacts 61 is removed in order to form recesses in the region of contacts 61 (contact recesses). The result is best shown in the sectional views depicted by FIGS. 6a and 6b. A storage element contact 61 is connected to a storage element contact portion 22 of a selection transistor and is laterally surrounded by an isolating region 8 comprising the isolating spacers 82 and the isolation region 88. Further can be seen from FIG. 6b that a shallow trench isolation 81 is located between neighboring active areas.

The removal of the upper portion of the storage element contacts 61 is performed selectively with respect to the silicon oxide of the surrounding isolating region 8 and a silicon nitride cap 51 of the bit lines 5 such that a recess 62 is formed that is at least partially delimited by the isolating region 8 (i.e., by the spacers 82 and the isolating region 88). The etching of the conductive material of the contacts (e.g., poly silicon) thus reduces the height measured in a direction perpendicular to the substrate surface of the storage element contacts 61. Although dry etching is suited for etching the conductive material of the contacts, wet etching is also possible for forming the contact recesses.

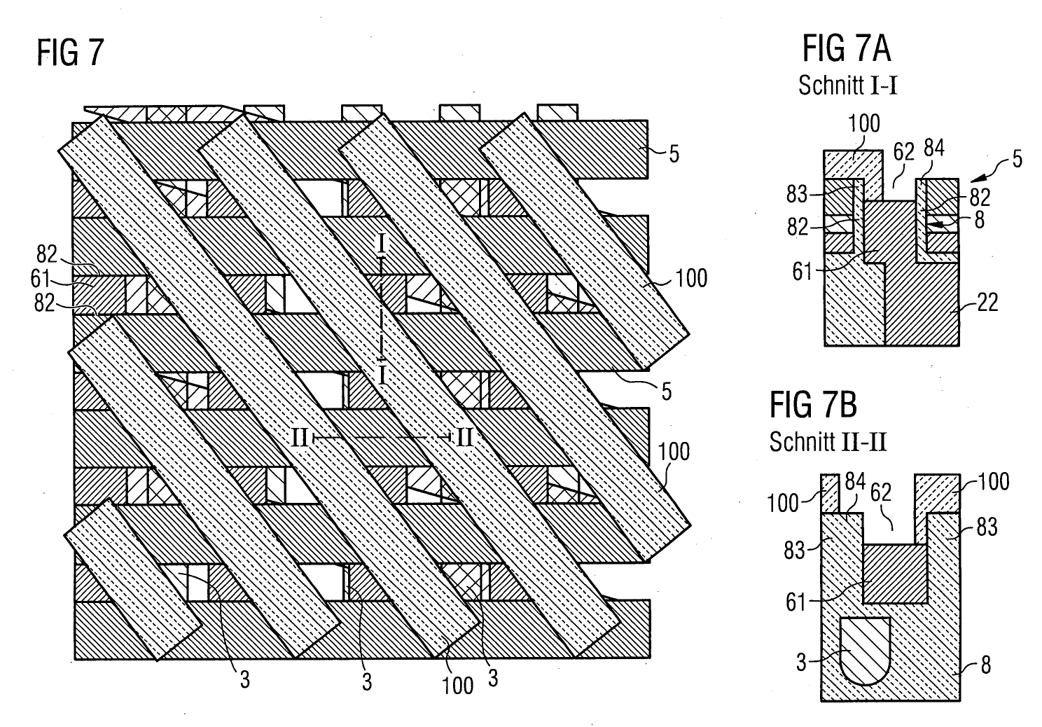

Referring to FIGS. 7, 7a and 7b, a mask layer comprising a plurality of longitudinal and essentially parallel extending structures in the form of stripes 100 (resist stripes or hard mask stripes) is formed in a further lithography step. The resist stripes 100 are arranged in such a manner that they partially overlap with the contacts 61. For this, the resist stripes 100 extend obliquely with respect to the columns formed by the contacts 61 (which in turn extend basically perpendicular to the bit lines 5). The oblique resist strips 100 also partially overlap with the isolating region 100 such that a part 83 is covered by the resist stripes 100, whereas another part 84 of the isolating region 8 is not covered (see sectional views in FIGS. 7a and 7b).

Although the resist stripes 100 run obliquely with respect to the columns (corresponding to the former conductive stripes 6) formed by the contacts 61, it is also possible and covered by the invention that mask stripes are used that run parallel to the contact columns (i.e., perpendicular to the bit lines). Also, the resist stripes do not necessarily have to overlap with the contacts 61. Further, it is also covered by the invention that the mask layer comprises structures that does not extend straight but in a different manner, e.g., step like or meandering.

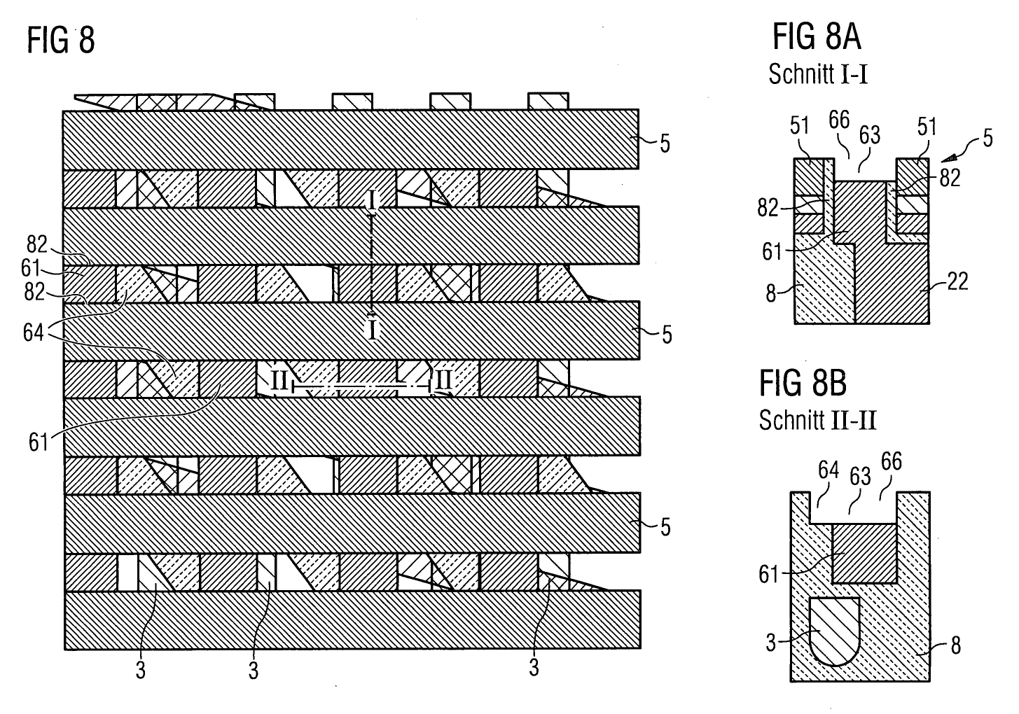

Referring to FIG. 8, an etching step is performed in order to reduce the height of the isolating region 8 (more particular, the height of the parts 84 of the isolating region 8 that are not covered by the resist mask 8). The result of the etching is best shown in the sectional views of FIGS. 8a and 8b. Since the etching of the isolating material of isolating region 8 (e.g., silicon oxide) is performed selectively with respect to the conductive material of the storage element contacts 61 and the silicon nitride material of the bit line cap 51, the height of the portions 84 of the isolating region are reduced to approximately the height of the reduced contacts 61 (i.e., the surface of the isolating parts 84 facing away from the substrate extends on the level with the upper surface of the contacts 61 after the etching).

This results in an enlarged recess 63 that essentially consists of a basic portion 66 and an extension 64 that corresponds to a part of the isolating portions 84 that was not covered by the resist stripe and is now removed. The extension 64 extends essentially in a direction parallel to the bit lines 5 and parallel to the substrate surface as shown in FIG. 8 and the corresponding sectional view in FIG. 8b.

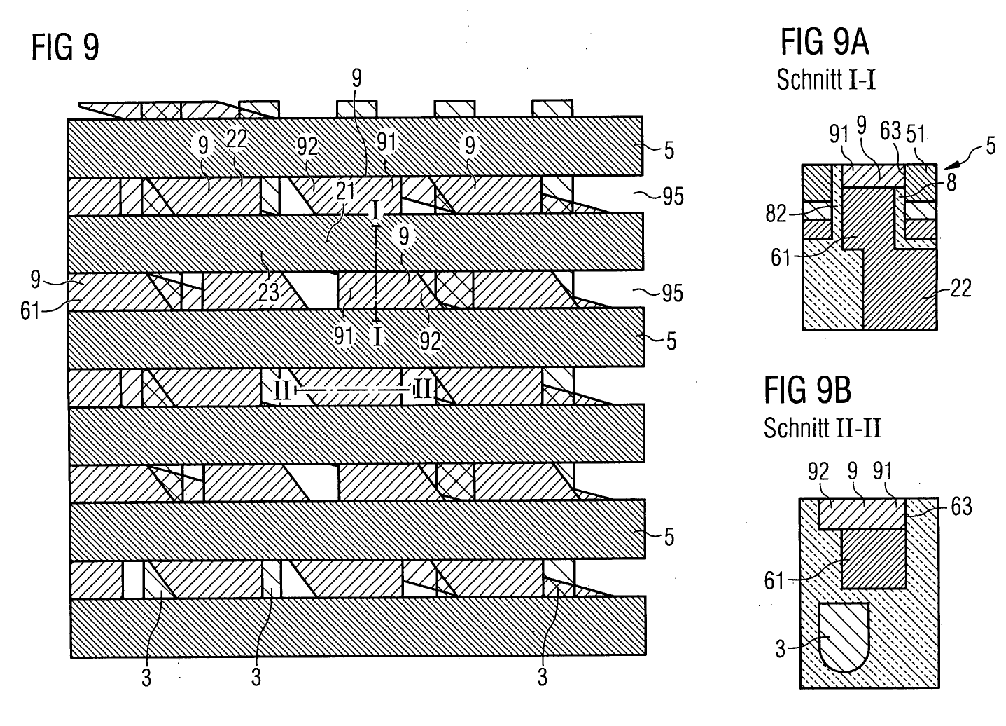

In a further step, as shown in FIG. 9, the enlarged recesses 63 above the storage element contacts 61 are used for forming enlarged contact areas in the form of contact pads 9. For this the enlarged recesses 63 are filled with conductive material, wherein the filling comprises forming a silicide layer (e.g., titanium silicide or cobalt silicide) on the structure of FIG. 8. Subsequently, a metal layer such as a tungsten layer is deposited on the silicide layer. The silicide layer is a transition layer permitting the connection between the metal layer and poly silicon used as conductive material for forming the contacts 61. It is pointed out that the recess filling can be performed simultaneously with filling periphery contacts of the semiconductor device to be produced. Also, the silicidation typically forms part of forming periphery contacts such that no additional step is needed for filling the enlarged recesses 61.

Although the illustrated embodiment comprises removing upper portions of the contacts 61 for generating contact recesses, this is not a necessary step for carrying out the invention. According to the invention, a portion adjacent to a contact of the isolating material has to be reduced in height in order to generate a plurality of recesses (in the isolating region) adjacent to the contact. These recesses are filled with conductive material, whereby contacts having enlarged contact areas are formed. Optionally, contact recesses can be additionally formed.

After forming the silicide and depositing the metal layer for filling the recesses, a chemical mechanical polishing step is performed. The polishing is performed with stop on the isolation material 8 in order to remove the conductive material (silicide and tungsten) outside the enlarged recesses 63. The result is best shown in FIGS. 9a and 9b. The metal now only fills the recess 63 and does not protrude over the surrounding isolation 8 (i.e. isolating spacer 82 and the isolating region 88). Corresponding to the form of the recesses, the thus formed contact pads 9 comprise a basic portion 91 and an extension 92 extending from the basic portion 91 parallel to the substrate surface.

The contact pads 9 are used for connecting a storage element with the storage element contact portion of a selection transistor via a contact 61. The enlarged contact areas 9 provide a lower contact resistance between the contacts 61 and a storage element. Furthermore, a greater flexibility for the storage element layout is achieved. Thus, the storage elements can, for example, be arranged in a checkerboard layout, wherein a bigger overlay between the contact areas and the storage elements is obtained due to the enlarged contact pads. This results in a more stable production of the semiconductor device and in less strict lithography requirements when fabricating the storage elements. Typically, capacitors in the form of elliptically shaped cylinders are used. With the inventive method, the elliptical shape of the cylinders can be reduced.

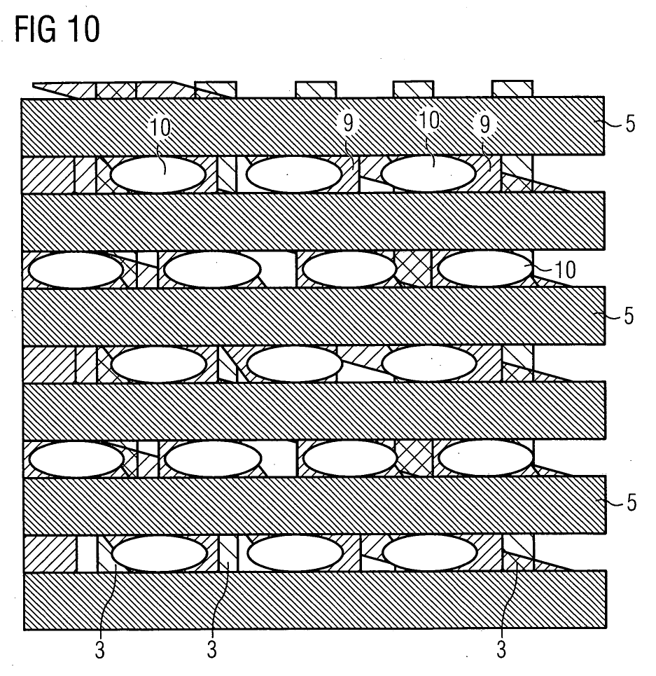

A checkerboard like arrangement of storage elements in the form of storage capacitors 10 is shown in FIG. 10. As can be further seen, the extensions 92 of the contact pads 9 extend from the basic portion 91 (that is aligned with the underlying contacts 61) basically in one direction, only. This direction is the same for all contact areas 9 of one row 95 of contacts (between the bit lines 5). However, the direction in which the extensions 92 extend from the basic portion 91 alternates such that the extensions of the contact pads 9 of one contact row 95 extend in a first direction, whereas the extensions of a neighboring contact pad row extend in a second direction opposite to the first direction. Because of this complementary arrangement of the extensions 91, the overlay to the storage element contact is significantly enlarged due to the enlarged contact pads 9.

The foregoing detailed description discloses only the preferred embodiments of the invention, modifications of the above disclosed device and method that fall within the scope of the invention will be apparent to those of ordinary skill in the art. For example, the invention is not restricted to a particular kind of a semiconductor device, i.e., it is not restricted to storage cells. In particular, the invention least of all is restricted to a certain kind of a storage cell; it is applicable to different kinds of storage cells such as DRAM, FRAM, CBRAM (Conductive Bridging Random Access Memory) or PCRAM (Phase Change Random Access Memory) devices. The concept can be generally applied for enlarging contacts areas arranged in a regular (e.g., line like) pattern. More particularly, it can be used for transforming line like arranged contact portions into a checkerboard layout or vice versa. Employing the invention, a line like arrangement of contact portions can be transformed in a checkerboard like arrangement without an additional contact level.

Further, alternative materials can be employed during the fabrication of the inventive device or within the inventive device. For instance, different conductive materials can be used instead of poly silicon and different insulating materials can be used. For example, silicon nitride can be employed instead of silicon oxide for forming the isolating regions.

What is claimed is:

1. Method of fabricating a semiconductor device, comprising the steps of:
providing a substrate with a plurality of contact portions;
forming a plurality of electrical contacts such that a contact is electrically connected to each of the contact portions, the contacts each comprising a contact area for connecting to a further part of the semiconductor device;
forming an isolating region such that each contact is at least partially surrounded by the isolating region;
performing an etching step in order to form a plurality of recesses in the isolating region, wherein a recess is formed adjacent to each contact; and
filling the recesses with conductive material in order to enlarge the contact areas of the contacts.

2. The method according to claim 1, further comprising performing an etching step in order to reduce the height of the contacts in a direction perpendicular to the substrate surface such that contact recesses are formed that are at least partially delimited by the isolating region.

3. The method according to claim 2, wherein the contact recesses are filled with conductive material.

4. The method according to claim 3, wherein the contact recesses and the recesses in the isolating material are filled with the same conductive material.

5. The method according to claim 1, wherein filling the recesses comprises
forming a layer of the conductive material; and
removing portions of the conductive material located outside of the recesses.

6. The method according to claim 5, wherein a polishing or an etch step with stop on the isolating material is performed in order to remove the conductive material outside of the recesses.

7. The method according to claim 1, wherein the substrate further comprises a plurality of further contact portions and wherein a plurality of essentially parallel contact lines that electrically connect to the further contact portions are formed.

8. The method according to claim 7, wherein forming the plurality of electrical contacts comprises generating a plurality of parallel conductive stripes that extend inclined with respect to the contact lines.

9. The method according to claim 8, further comprising removing portions of the conductive stripes located above the contact lines.

10. The method according to claim 9, wherein a polishing or an etch step with stop on the contact line is performed in order to remove the portions above the contact lines of the conductive stripes such that a plurality of electrical contacts arranged along essentially parallel columns (contact columns) are formed.

11. The method according to claim 1, wherein a mask layer is formed before the etching step for forming the recesses in the isolating material, the mask layer comprising openings, wherein an opening is arranged adjacent to each electrical contact.

12. The method according to claim 11, wherein a mask layer is formed before the etching step for forming the recesses in the isolating material, the mask layer comprising a plurality of structures that each extend essentially parallel to the contact columns.

13. The method according to claim 11, wherein a mask layer is formed before the etching step for forming the recesses in the isolating material, the mask layer comprising a plurality of structures that each extend essentially obliquely with respect to the contact columns.

14. The method according to claim 13, wherein the mask layer comprises a plurality of continuous structures that extend essentially parallel to one another.

15. The method according to claim 14, wherein the structures extend longitudinally, step like or meandering.

16. The method according to claim 13, wherein a structure of the mask layer comprises a plurality of spaced mask elements arranged in a row.

17. The method according to claim 1, wherein a plurality of functional structures is fabricated such that a functional structure is connected to each contact via the enlarged contact area of the contact.

18. The method according to claim 17, wherein the functional structures are arranged in a checkerboard layout.

19. The method according to claim 7, wherein each of the contact portions and the further contact portions comprise doped regions in the substrate or in a layer arranged on the substrate.

20. The method according to claim 1, wherein the electrical contacts comprise poly silicon or a metal.

21. The method according to claim 1, wherein the isolating region comprise silicon oxide or silicon nitride.

22. The method according to claim 13, wherein the structures of the mask layer are formed as photo resist or hard mask structures.

23. The method according to claim 1, wherein the conductive material comprises a metal or poly silicon.

24. A semiconductor device, comprising:
a substrate with a plurality of contact portions;
a plurality of electrical contacts, wherein an electrical contact is connected to each contact portion, wherein
each electrical contact comprises a contact area for connecting to a further part of the semiconductor device, the contact area comprising:
a basic portion aligned with the rest of the contact; and
an extension that extends from the basic portion essentially parallel to the substrate surface.

25. The semiconductor device of claim 24, wherein the contact area is located at an end of the contact that faces away from the substrate.

26. The semiconductor device of claim 24, wherein the extension of the contact area essentially extends from the basic portion in one direction, only.

27. The semiconductor device of claim 24, wherein the contacts have an essentially rectangular cross section parallel to the substrate surface.

28. The semiconductor device of claim 27, wherein the basic portion has a cross section parallel to the substrate surface that consists of an essentially rectangular portion corresponding to the cross section of the contact.

29. The semiconductor device of claim 28, wherein the extension of the contact area has a cross section that is one of a rectangle, a triangle or a trapezoid that connects to the basic portion.

30. The semiconductor device of claim 24, wherein contacts are at least partially delimited from another by an isolating region.

31. The semiconductor device of claim 24, wherein the contact area essentially does not protrude over the isolating region in a direction perpendicular to the substrate surface.

32. The semiconductor device of claim 24, wherein the substrate comprises a plurality of further contact portions and wherein a plurality of parallel contact lines is arranged that electrically connect to the further contact portions.

33. The semiconductor device of claim 32, wherein the extensions of the contact areas extend essentially parallel to the contact lines.

34. The semiconductor device of claim 33, wherein the contacts are arranged in a plurality of contact rows extending essentially parallel to the contact lines.

35. The semiconductor device of claim 34, wherein the extension of the contact area of a contact belonging to a first contact row extends from the basic portion along a first direction, whereas the extension of the contact area of a contact belonging to a second contact row neighboring the first row extends along a second direction that runs opposite to the first direction.

36. The semiconductor device of claim 24, further comprising a plurality of functional structures that are electrically connected to the contacts via the contact area of the contacts.

37. The semiconductor device of claim 36, wherein the functional structures are arranged in a checkerboard layout.

38. The semiconductor device of claim 37, wherein a functional structure comprises a storage capacitor.

39. The semiconductor device of claim 38, wherein a functional structure comprises a conductive pad.

40. The semiconductor device of claim 24 formed as a memory device.

41. The semiconductor device of claim 40, wherein the memory device is selected from the group consisting of a DRAM, a FRAM, a CBRAM and a PCRAM device.

42. The semiconductor device of claim 41, wherein the contact portions comprise source/drain regions of a selection transistor.
